(19) United States
(12) Patent Application Publication
(10) Pub. No.: US 2025/0022918 A1
(43) Pub. Date: Jan. 16, 2025

(54) SEMICONDUCTOR DIE WITH A SILICON CARBIDE SUBSTRATE

(71) Applicant: Infineon Technologies AG, Neubiberg (DE)

(72) Inventors: Christian HECHT, Buckenhof (DE); Wolfgang BERGNER, Klagenfurt am Wörthersee (AT); Larissa WEHRHAHN-KILIAN, Erlangen (DE)

(21) Appl. No.: 18/768,307

(22) Filed: Jul. 10, 2024

(30) Foreign Application Priority Data
Jul. 11, 2023 (DE) 102023206580.0
Jun. 10, 2024 (DE) 102024205356.2

(51) Int. Cl. H01L 29/16; H01L 21/02; H01L 23/04; H01L 29/06; H01L 29/36; H01L 29/78

(52) U.S. Cl. CPC H01L 29/1608; H01L 21/02447; H01L 21/02694; H01L 29/0603; H01L 29/1604; H01L 29/36; H01L 23/04; H01L 29/7813

(57) ABSTRACT

The disclosure relates to a semiconductor die with a semiconductor device in a semiconductor body, the semiconductor body comprising a silicon carbide substrate; an epitaxial silicon carbide layer system on a first side of the silicon carbide substrate; an interruption layer; wherein the interruption layer is embedded either into the silicon carbide substrate or into the epitaxial silicon carbide layer system, in each case at a vertical distance from the first side of the silicon carbide substrate.

### RELATED APPLICATIONS

This application claims priority to German Patent Application No. 102023206580.0, filed on Jul. 11, 2023, entitled “SEMICONDUCTOR DIE WITH A SILICON CARBIDE SUBSTRATE”, which is incorporated by reference herein in its entirety. This application also claims priority to German Patent Application No. 102024205356.2, filed on Jun. 10, 2024, entitled “SEMICONDUCTOR DIE WITH A SILICON CARBIDE SUBSTRATE”, which is incorporated by reference herein in its entirety.

### TECHNICAL FIELD

The present disclosure relates to a semiconductor die with a semiconductor device in a semiconductor body which comprises a silicon carbide substrate.

### BACKGROUND

Silicon carbide (SiC) has a comparably wide bandgap, e. g. compared to silicon. This can for instance facilitate high-voltage and/or high current capabilities and be of particular interest for power semiconductor devices. These find applications in various fields such as high-voltage DC transmission, for instance in offshore wind farms or the like.

### SUMMARY

Examples of the present application are directed at an advantageous semiconductor die with a silicon carbide substrate.

In an embodiment, a semiconductor die comprises a semiconductor device in a semiconductor body. In addition to a silicon carbide (SiC) substrate, the semiconductor body comprises an epitaxial SiC layer system and an interruption layer. The epitaxial SiC layer system is arranged on a first side of the SiC substrate. The interruption layer is embedded either into the SiC substrate or into the epitaxial SiC layer system, in each case at a vertical distance from the first side of the SiC substrate. In other words, the interruption layer can be arranged below the first side in the SiC substrate or above the first side in the epitaxial SiC layer system, but in each case it is spaced apart vertically from the first side.

The interruption layer can be an amorphous and/or porous layer as well as a highly doped layer. It can form or serve as an “interruption” of the crystal structure or “interrupt” (e. g. strongly decrease) an electron-hole (eh) recombination, e. g. shield the interface between the substrate and the epitaxial layer system from the eh recombination. So-called conversion points can in particular be located at this interface (“first side” of the SiC substrate) between the SiC substrate and the epitaxial SiC layer system, which can result from a conversion of basal plane dislocations (BPD) in the substrate to threading edge dislocations (TED) in the epitaxial layer system.

While the TEDs may be less critical, a stacking fault growth may occur once the ch recombination reaches the conversion points. Though this bipolar degradation occurs in bipolar mode, the resulting stacking faults remain in unipolar mode and can for instance effect the electrical properties of the device. The interruption layer embedded into the substrate or epitaxial layer system can for example stop or reduce the stacking fault growth physically due to the “interrupted” crystal structure and/or “interrupt”, for instance strongly decrease, the eh recombination above the interface.

Particular embodiments and features are provided in this description and the figures and in the dependent claims. Therein, the individual features shall be disclosed independently of a specific claim category, the disclosure relates to apparatus and device aspects, but also to method and use aspects. If for instance a die manufactured in a specific way is described, this is also a disclosure of a respective manufacturing process, and vice versa. In general words, an approach of this application is to introduce an interruption layer into a semiconductor body with an SiC substrate and an epitaxial SiC layer system, in particular at a vertical distance from the interface between the substrate and the epitaxial layer system.

The SiC substrate may have a main extension plane that is spanned by lateral directions (also referred to as “horizontal directions”). The vertical direction may run essentially perpendicular to the lateral directions and an extension of the SiC substrate in the vertical direction may be small compared to the extension of the SiC substrate in the lateral directions. In some examples, the SiC substrate may comprise or essentially consist of 2H-SiC (SiC of the 2H polytype), 6H-SIC, 3C-SiC or 15R-SiC. According to an example, the semiconductor material is silicon carbide of the hexagonal 4H polytype (4H-SiC). An off-axis angle of the SiC substrate may be in a range from 2° to 8°, typically 4°. The first side of the SiC substrate then may be ribbed such that sections of the first side may be tilted with respect to the lateral directions and/or the horizontal direction. For example, a main crystal axis (e.g. the <0001> axis) of the SiC substrate may enclose an angle (e.g. the off-axis angle) with the vertical direction.

As it is a “layer”, the interruption layer may have a larger lateral extension than thickness, e. g. a larger extension in each lateral direction compared to its extension in the vertical direction. Referring to the area of the die, the interruption layer can for instance extend over at least 50%, 70% or 90% of the area of the die. In an embodiment, the interruption layer extends over the whole area of the die.

The “vertical distance” is taken in the vertical direction. In detail, it is taken as the smallest distance, namely clearance (not center to center-distance). As per definition, all layers or layer systems of the semiconductor body have a first side and a vertically opposite second side, the first sides respectively oriented in the same vertical upward direction and the second sides respectively oriented in the same vertical downward direction. For instance, the first side of the epitaxial SiC layer system faces away from the SiC substrate and/or the second side of the SiC substrate faces away from the epitaxial SiC layer system. “Above” means closer to the first side of the semiconductor body and “below” means closer to the second side of the semiconductor body.

The epitaxial SiC layer system comprises at least one epitaxial SiC layer. In particular, it can comprise a plurality of stacked layers, for instance a device layer or layers, in particular with a buffer layer below. In the device layer(s), an active region or regions of the device can be arranged. Alternatively or in addition to an n-region, the device can in particular comprise a p-region, e. g. depending on the device type an anode contact in case of a diode or a body region in case of an nFET.

As discussed above, the interruption layer is embedded into the SiC substrate or into the epitaxial SiC layer system. “Embedded” may refer to the vertical direction, so that in case of the SiC substrate, for example, an upper end (first side) of the interruption layer may be arranged below the first side of the SiC substrate and a lower end (second side) of the interruption layer may be arranged above the second side of the SiC substrate. In case of the epitaxial SiC layer system, for example, an upper end (first side) of the interruption layer may be arranged below the first side of the SiC epitaxial layer system and a lower end (second side) of the interruption layer may be arranged above the second side of the epitaxial SiC layer system. In other words, when embedded into the SiC substrate, a respective portion of the SiC substrate is respectively arranged above and below the interruption layer. When embedded into the epitaxial SiC layer system, a respective portion of the epitaxial SiC layer system is respectively arranged above and below the interruption layer.

Generally, the semiconductor body can comprise an additional (“second”) interruption layer in addition to the (“first”) interruption layer discussed so far. For instance, one interruption layer can be embedded into the SiC substrate while the other one is embedded into the epitaxial SiC layer system. Alternatively, the semiconductor body may comprise one single interruption layer only, and the disclosure shall cover both options unless indicated otherwise. In other words, “the interruption layer” can be the sole interruption layer in the semiconductor body or can be a first interruption layer combined with a second interruption layer.

In an embodiment, the vertical distance between the first side of the SiC substrate and the interruption layer is at least 0.1 μm, in particular at least 0.2 μm. Upper limits of the vertical distance can for instance be 1 μm, 0.7 μm or 0.5 μm. The interruption layer is arranged in a vertical distance but not too far from the interface/first side of the SiC substrate.

In an embodiment, the interruption layer has a vertical thickness of at least 0.1 μm (or at least 0.2 μm or at least 0.3 μm or at least 0.5 μm) and/or of not more than 5 μm. As to the vertical distance, the thickness is taken in the vertical direction. Depending for instance on the specific interruption layer type and its manufacturing, a limitation of the thickness can for example have economic advantages.

In an embodiment, the interruption layer is a highly doped layer. In case of the epitaxial SiC layer system comprising a buffer layer, the highly doped interruption layer can in particular have a higher doping concentration than the buffer layer. When arranged above the interface, namely embedded into the epitaxial SiC layer system, the shielding properties of the highly doped interruption layer can strongly decrease the eh recombination above the interface with the conversion points. Alternatively or in addition, the high dose implantation can destroy the crystal structure. Thus, the high dose implantation can also be a way of manufacturing an amorphous and/or porous layer which is applied due to the physical interruption of the crystal structure, for this reason alone or in combination with the shielding properties.

In an embodiment, the interruption layer is an amorphous and/or porous layer. When embedded into the epitaxial SiC layer system, the amorphous/porous interruption layer can for instance stop or interrupt the dislocations themselves, namely the stacking fault growth from the interface towards the first side of the semiconductor body. However, this growth towards the first side can also be interrupted when the amorphous/porous interruption layer is embedded into the SiC substrate, see in detail below. As an alternative to the high dose implantation, the amorphous/porous layer can for instance be formed by a laser irradiation and/or a porosification.

In an embodiment, the epitaxial SiC layer system comprises a device layer and a buffer layer which is arranged between the device layer and the SiC substrate. In particular, the buffer layer may lie directly adjacent to the first side of the SiC substrate and/or the device layer may lie directly adjacent to the first side of the buffer layer. The doping concentration of the buffer layer may be higher than in the device layer, for instance higher than in a region of the device layer directly adjacent to the buffer layer. In other words, the doping concentration in the buffer layer can for instance be higher than in a drift region formed in the device layer. As to a highly doped interruption layer, its doping concentration can be higher than that of the buffer layer.

Independently of these details, the buffer layer arranged above the interface can for instance shield the conversion points from the device layer. The hole density can become particularly high in the drift region, the holes reaching the conversion points for example with increasing current density. Though this might be counteracted by an increasing thickness and doping concentration of the buffer layer, there can be limitations for economic and technical reasons. In this respect, an approach of this application is to combine the buffer layer with the interruption layer.

In an embodiment, the interruption layer is embedded into the buffer layer so that a lower portion of the buffer layer is arranged below the interruption layer and an upper portion of the buffer layer is arranged above. In case of an amorphous/porous interruption layer, the interruption of the crystal structure can for instance stop a further growth of the dislocations or stacking faults when the eh recombination reaches the conversion points despite of the buffer layer. When the interruption layer has, alternatively or in addition, a higher doping concentration compared to the buffer layer, it can for instance provide for a certain separation of the eh recombination and the conversion points at the interface, e. g. strongly decrease the eh recombination and dislocation growth, thus.

In an embodiment relating to the amorphous and/or porous interruption layer, it is embedded into the SiC substrate. In other words, the interruption layer is arranged at the vertical distance below the interface/first side of the substrate. For instance, the growth of a dislocation from the interface upwards can, for geometric reasons, result in or require a “mirror image dislocation” running downwards in the substrate. The latter can be stopped by the amorphous/porous layer embedded into the substrate, which can vice versa also stop the growth upwards.

In an embodiment, a metallization layer is arranged on the second side of the SiC substrate, which is the second side of the semiconductor body. In other words, the die has a backside metallization, for instance in combination with a frontside metallization on the first side of the semiconductor body. The metallization layer on the backside can for instance serve for a mounting of the die in a package and/or in particular as an electrical contact for the device. This applies in particular for a vertical device having its load contacts at opposite sides of the semiconductor body.

In an embodiment, the device is an FET having a source region and a drain region. In particular, it can be a vertical FET having its source region and drain region at opposite sides of the semiconductor body, e. g. the source region at the first side and the drain region at the second side. Then, the backside metallization may in particular be or may be comprised by the drain metallization of the vertical FET.

In an embodiment, the die comprises an additional (“second”) interruption layer which can in particular be arranged “complementary” to the first interruption layer. For instance, one interruption layer can be embedded into the SiC substrate while the other interruption layer is embedded into the epitaxial SiC layer system. The additional or “second” interruption layer is not necessarily arranged at a vertical distance from the interface between the substrate and the epitaxial layer system but can in general lie directly adjacent to the interface. Such an interruption layer, in particular disposed between the SiC substrate and a buffer layer (see above), shall also be disclosed independently of a vertical distance from the interface and independently of whether only one or two interruption layers are present. In other words, it shall be disclosed a semiconductor die with a semiconductor device in a semiconductor body, the semiconductor body comprising: a silicon carbide substrate; an epitaxial silicon carbide layer system on a first side of silicon carbide substrate; an interruption layer; wherein the epitaxial silicon carbide layer system comprises a buffer layer, and wherein the interruption layer is arranged on the first side of the silicon carbide substrate, between the silicon carbide substrate and the buffer layer. In particular, this interruption layer can lie directly adjacent to the first side of the SiC substrate.

The application relates also to a package comprising the semiconductor die and a casing in which the die is mounted and electrically contacted. In particular, a backside metallization (see above) of the die can be contacted in the casing, for instance connected to a pin of the package. In the example just given, this can be the drain pin of the package.

The application further relates to a method of manufacturing a semiconductor die or package. In addition to an epitaxial deposition of an epitaxial SiC layer system onto a SiC substrate, the method comprises a formation of the interruption layer.

An interruption layer can in particular be formed by a high dose implantation (“highly doped layer”, see above) which can be applied due to the shielding properties and/or an accompanying destruction of the crystal structure. Alternatively, an amorphous/porous layer can be formed by laser irradiation, wherein SiC can for instance be split into Si and C in the focus of the laser. In particular, the focal plane of the laser can be chosen slightly below the irradiation surface, for instance slightly below the first side of the SiC substrate to embed the interruption layer into it (or slightly below the first side of the buffer layer to embed the interruption layer into it).

Alternatively, the amorphous/porous layer can be formed by porosification, namely in an etch process. These different manufacturing methods can be combined or applied as alternatives. Depending on the location of the interruption layer, its formation can be implemented at different steps of the process flow. For instance, the interruption layer embedded into the SiC substrate may be formed prior to the deposition of the epitaxial SiC layer system.

Vice versa, the formation of the interruption layer embedded into the epitaxial SiC layer system can be integrated into the deposition of it. In particular, the interruption layer can be formed after a deposition of the buffer layer, for instance at least after the deposition of the lower portion of it, and prior to the deposition of the device layer. In an embodiment, the interruption layer is made after a deposition of the lower portion of the buffer layer and prior to a deposition of the upper portion of the buffer layer. In particular, a high dose implantation step may be implemented in between to form the highly doped interruption layer embedded into the buffer layer.

### BRIEF DESCRIPTION OF THE DRAWINGS

Below, the die and other embodiments are discussed in further detail by means of exemplary embodiments. Therein, the individual features can also be relevant in a different combination.

FIG. 1 shows a die with an epitaxial SiC layer system on an SiC substrate into which an interruption layer is embedded;

FIG. 2 shows a die with an SiC substrate and an epitaxial SiC layer system into which an interruption layer is embedded;

FIG. 3 shows a cross-sectional view of a device formed in the die;

FIGS. 4a-c shows schematic views of different possibilities for manufacturing the interruption layer;

FIG. 5 shows a cross-section through a package with the die;

FIG. 6 shows some manufacturing steps in a flow diagram.

### PARTICULAR EMBODIMENTS

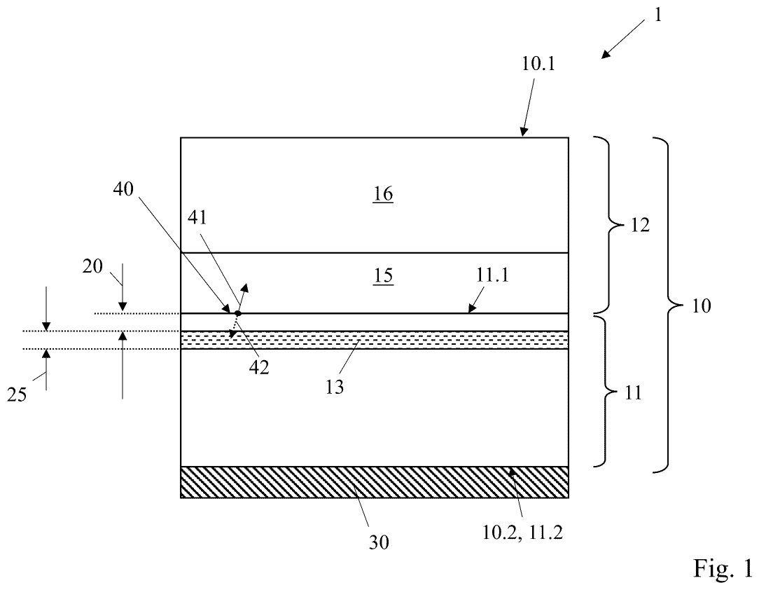

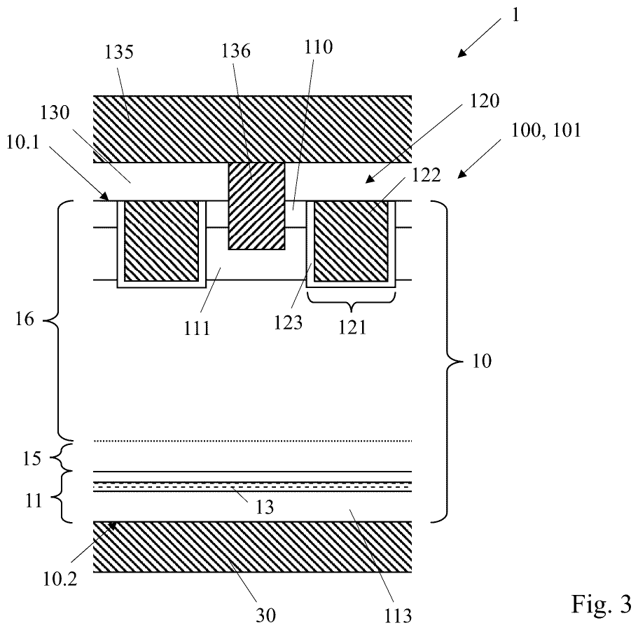

FIG. 1 shows a schematic cross-section through a semiconductor die 1 with a semiconductor body 10. The semiconductor body 10 comprises a silicon carbide (SiC) substrate 11 and an epitaxial SiC layer system 12. The epitaxial SiC layer system 12 is epitaxially deposited onto a first side 11.1 of the SiC substrate 11, in the example shown it comprises a device layer 16 and a buffer layer 15 below. On the second side 11.2 of the SiC substrate 11, which is the second side 10.2 of the semiconductor body 10, a metallization layer 30 is arranged, see FIGS. 3 and 5 for further details.

In addition, the semiconductor body 10 comprises an interruption layer 13. In the embodiment of FIG. 1, it is embedded into the SiC substrate 11, namely arranged at a vertical distance 20 from the first side 11.1 which is the interface between the SiC substrate 11 and the epitaxial SiC layer system 12. At the interface, conversion points 40 can be located (only one shown for the sake of clarity), that can be a starting point for the growth of a dislocation or stacking fault 41, e. g. in bipolar mode. The interruption layer 13 provided as an amorphous/porous layer can interrupt the crystal structure and stop a mirror stacking fault 42. In consequence, it can also interrupt a further upward propagation of the stacking fault 41.

The interruption layer 13 may, by way of example, have a vertical thickness 25 of around 2.5 μm. The vertical distance 20 can for instance be around 0.5 μm. The interruption layer 13 may be manufactured prior to the deposition of the epitaxial SiC layer system, for instance by a laser irradiation through the first side 11.1 with a focal plane displaced slightly downward, see in detail below.

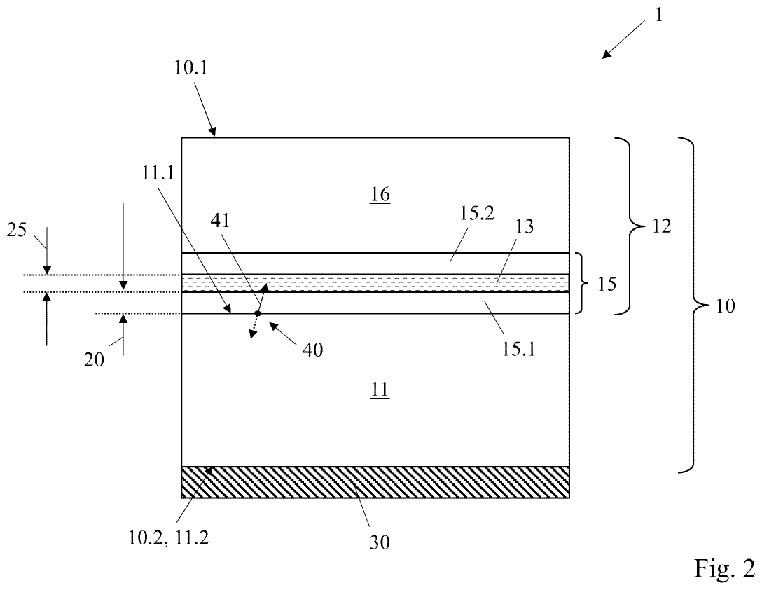

In the embodiment of FIG. 2, the interruption layer 13 is embedded into the buffer layer 15. A lower portion 15.1 of the buffer layer is arranged below the interruption layer 13 and an upper portion 15.2 is arranged above, namely between the interruption layer 13 and the device layer 16. Again, the interruption layer 13 is spaced apart from the interface between the SiC substrate 11 and the epitaxial SiC layer system 12.

On the one hand, in case of an amorphous/porous interruption layer 13, the interruption of the crystal structure can stop a growth of the stacking fault 41 physically, as illustrated schematically. Alternatively or in addition, the interruption layer 13 can be highly doped and provide for a shielding of the interface from the eh recombination, for example in addition to a shielding by the buffer layer 15. To summarize, the interruption layer 13 can decrease the eh recombination (which triggers the stacking fault growth) and/or can stop the growth once initiated due to the interrupted crystal structure.

For manufacturing the die 1 of FIG. 2, the interruption layer 13 can for instance be formed after the deposition of the lower portion 15.1 of the buffer layer 15 and prior to the deposition of its upper portion 15.2, for instance by a high-dose implantation in between. Alternatively, the buffer layer 15 can be deposited in one step, the interruption layer 13 being formed thereafter, for instance by laser irradiation.

FIG. 3 shows a schematic cross-section of the die 1 and illustrates a semiconductor device 100, in the example shown a vertical transistor device 100. Generally, in this disclosure, the like reference numerals indicate the like elements or elements having the like function and reference is always made to the description of the respectively other figures as well. Of course, any measure or ratio in this schematic drawing is not to scale.

The vertical transistor device 101 comprises a source region 110 at the first side 10.1 of the semiconductor body 10 and a drain region 113 at the vertically opposite second side 10.2. In between, its body region 111 and drift region 112 are arranged. The drift region 112 is made of the same doping type but with a lower doping concentration compared to the drain region 113. In case of an nFET, the source region 110, drift region 112 and drain region 113 are n-doped, whereas the body region 111 is p-doped.

A gate region 120 is arranged laterally aside the body region 111 in a trench 121. It comprises a gate electrode 122 and a gate dielectric 123 which capacitively couples the gate electrode 122 to the body region 111. On the first side 10.1, an insulating layer 130 with a frontside metallization layer 135 on top are arranged. The frontside metallization layer 135 is the source contact, it connects to the source region 110 and body region 111 via a contact plug 136. The metallization layer 30 on the second side 10.2 connects to the drain region 113 and is used as drain contact.

The source region 110, body region 111 and drift region 112 are formed in the device layer 16. Below, the buffer layer 15 is arranged for a certain shielding of the interface from the eh recombination, see above. In the example shown, the interruption layer 13 is embedded into SiC substrate as explained for FIG. 1, but the interruption layer could also be embedded into the buffer layer 15 as illustrated in FIG. 2.

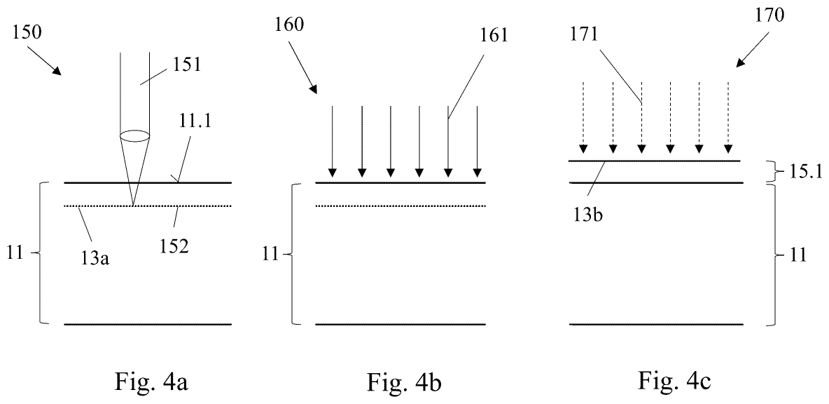

FIGS. 4 a-c illustrate different options to manufacture the interruption layer 13. FIG. 4a shows a laser irradiation 150, namely a laser beam 151 focused into a focal plane 125 below the first side 11.1 of the SiC substrate 11. In the focal plane 125, the crystal structure is destroyed locally, which gives an amorphous and/or porous layer 13a.

FIG. 4b illustrates an interruption layer formation by a porosification 160, namely by an etch agent 161. FIG. 4c illustrates a high dose implantation 170. In this case, the interruption layer shall be embedded into the buffer layer 15, and the doping agent 171 for the high dose implantation 170 is introduced after the deposition of the lower portion 15.1 of the buffer layer 15 and prior to the deposition of the upper portion 15.2 of it.

FIG. 5 shows a package 200 which comprises a casing 201 in which the semiconductor die 1 is mounted. In detail, the die 1 is placed on a heatsink 202, wherein the metallization layer arranged on the second side (not shown here), namely the drain metallization of the die 1, electrically connects to the heatsink 202. Via a respective pin 203, the drain contact can be connected. The die 1 is embedded into a mould compound 204, wherein further connection details are not shown here.

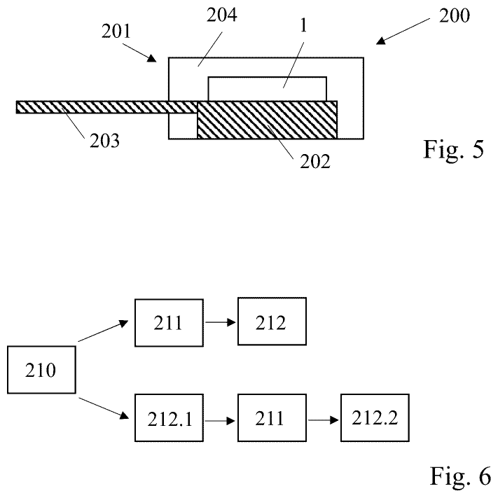

FIG. 6 summarizes some manufacturing steps. After providing 210 the SiC substrate, different options are possible. Either, the forming 211 of the interruption layer can be done prior to epitaxially depositing 212 the epitaxial SiC layer system. Alternatively, as illustrated in the lower path, the forming 211 of the interruption layer can be embedded between the deposition steps 212.1, 212.2, see also FIG. 4c.

1. A semiconductor die comprising:
a semiconductor device in a semiconductor body,
the semiconductor body comprising:
a silicon carbide substrate;
an epitaxial silicon carbide layer system on a first side of the silicon carbide substrate; and
an interruption layer;
wherein the interruption layer is at least one of:
embedded into the silicon carbide substrate at a vertical distance from the first side of the silicon carbide substrate; or
embedded into the epitaxial silicon carbide layer system at the vertical distance from the first side of the silicon carbide substrate.

2. The semiconductor die of claim 1, wherein the vertical distance between the first side of the silicon carbide substrate and the interruption layer is at least 0.1 μm and not more than 1 μm.

3. The semiconductor die of claim 1, wherein the interruption layer has a vertical thickness of at least 0.1 μm and not more than 5 μm.

4. The semiconductor die of claim 1, wherein the interruption layer is a highly doped layer.

5. The semiconductor die of claim 1, wherein the interruption layer is at least one of an amorphous layer or a porous layer.

6. The semiconductor die of claim 1, wherein the epitaxial silicon carbide layer system comprises a device layer and a buffer layer, the buffer layer being arranged between the device layer and the silicon carbide substrate and being doped with a higher doping concentration than the device layer.

7. The semiconductor die of claim 6, wherein the interruption layer is embedded into the buffer layer, a lower portion of the buffer layer arranged between the interruption layer and the silicon carbide substrate and an upper portion of the buffer layer arranged between the device layer and the interruption layer.

8. The semiconductor die of claim 5, wherein at least one of the amorphous layer or the porous layer is embedded into the silicon carbide substrate.

9. The semiconductor die of claim 1, comprising a metallization layer arranged on a second side of the silicon carbide substrate vertically opposite to the first side.

10. The semiconductor die of claim 1, wherein the semiconductor device is a vertical transistor device having a source region and a drain region at opposite sides of the semiconductor body.

11. The semiconductor die of claim 1, comprising an additional interruption layer which is vertically spaced apart from the interruption layer.

12. A package comprising:
the semiconductor die of claim 1, and
a casing,
wherein the semiconductor die is mounted and electrically contacted in the casing.

13. A method of manufacturing the semiconductor die of claim 1, comprising:
providing the silicon carbide substrate;
epitaxially depositing the epitaxial silicon carbide layer system on the first side of the silicon carbide substrate; and
forming the interruption layer.

14. The method of claim 13, wherein the interruption layer is formed by at least one of a laser irradiation, a porosification or a high dose implantation.

15. The method of claim 14, wherein forming the interruption layer is performed prior to epitaxially depositing the epitaxial silicon carbide layer system on the first side of the silicon carbide substrate.

16. The method of claim 13, wherein the highly doped layer is made by a high dose implantation between a deposition of the lower portion of the buffer layer and a deposition of the upper portion of the buffer layer.

17. A semiconductor body comprising:
a silicon carbide substrate;
an epitaxial silicon carbide layer system on a first side of the silicon carbide substrate; and
an interruption layer;
wherein the interruption layer is at least one of:
embedded into the silicon carbide substrate at a vertical distance from the first side of the silicon carbide substrate; or
embedded into the epitaxial silicon carbide layer system at the vertical distance from the first side of the silicon carbide substrate.

18. The semiconductor body of claim 17, wherein the interruption layer is at least one of an amorphous layer or a porous layer.

19. A method of manufacturing a semiconductor body, comprising:
providing a silicon carbide substrate;
forming an epitaxial silicon carbide layer system on a first side of the silicon carbide substrate; and
forming an interruption layer;
wherein the interruption layer is at least one of:
embedded into the silicon carbide substrate; or
embedded into the epitaxial silicon carbide layer system.

20. The method of claim 19, wherein the interruption layer is at least one of:
embedded into the silicon carbide substrate at a vertical distance from the first side of the silicon carbide substrate; or
embedded into the epitaxial silicon carbide layer system at the vertical distance from the first side of the silicon carbide substrate.
